(19) United States
(12) Patent Application Publication
(10) Pub. No.: US 2009/0086420 A1
(43) Pub. Date: Apr. 2, 2009

(54) RUGGED CONDUCTIVE HOUSING STRUCTURE FOR PORTABLE COMPUTING DEVICE DISPLAY

(75) Inventors: David Henry Stockham, Deer Park, WA (US); Jeffrey Lee Anderson, Spokane Valley, WA (US)

Correspondence Address: HUNTON & WILLIAMS LLP;INTELLECTUAL PROPERTY DEPARTMENT, 1900 K STREET, N.W., SUITE 1200, WASHINGTON, DC, 20006-1109, US

(73) Assignee: General Dynamics Itronix Corporation, Spokane Valley, WA (US)

(21) Appl. No.: 12/032,084

(22) Filed: Feb. 15, 2008

Related U.S. Application Data
(60) Provisional application No. 60/976,628, filed on Oct. 1, 2007.

(51) Int. Cl. H05K 7/00; H05K 5/00

(52) U.S. Cl. 361/679.26

(57) ABSTRACT

A portable computing device and a display housing module for a portable computing device is disclosed. The display housing module includes a conductive rear chassis, a display module and a front bezel. The display module is configured to display images and includes a backlight unit, a display panel, and a touch screen. The conductive rear chassis is strong, lightweight, and rigid. It is configured to receive and secure the display module and to protect the display module from shock events, drop events, and vibration. The conductive rear chassis may provide a conductive path to a ground connection. This prevents EMI from affecting an antenna signal by channeling EMI originating from noisy electronics to ground, thereby preventing unwanted EMI leakage outside of the display module. The conductive rear chassis is further configured to receive an environmental sealer around the perimeter of the housing. The conductive rear chassis is further configured for direct attachment to a front bezel. Attaching the front bezel to the conductive rear chassis creates pressure on the environmental sealer and allows the internal display parts to function properly without regard to environmental elements.

### CROSS REFERENCE TO RELATED APPLICATIONS

This application claims priority to provisional U.S. Application Ser. No. 60/976,628 filed Oct. 1, 2007 entitled “SuperStructure,” which is incorporated by reference herein in its entirety.

### BACKGROUND INFORMATION

1. Field of the Invention

The present invention relates to portable computing devices and to display module housing units for portable computing devices.

2. Description of the Related Art

Conventional portable computer display units typically utilize a flexible, non-rigid, non-conductive material to hold internal display parts. Such flexible, non-rigid display unit materials do not adequately protect against damage from shocks, drops, or vibration because the fragile internal glass components are not stabilized and are thus vulnerable upon impact. Some manufacturers, in an attempt to strengthen display units, construct an additional enclosure that goes around the existing non-rigid display unit. The additional enclosure is constructed as an outer unit, and the existing non-rigid display unit is a sub-enclosure. This additional outer main enclosure results in a thicker, bulkier display.

Additionally, conventional portable computer display assemblies use a non-conductive material to hold internal display parts. Non-conductive materials typically cannot shield against Electromagnetic Interference (“EMI”) or Radio Frequency Interference (“RFI”) noise. The terms “EMI” and “RFI” both refer to unwanted electromagnetic radiation signals that can potentially interfere with other signals. For purposes of brevity and consistency, this specification will use the term “EMI” when referring to such interference.

### SUMMARY OF THE INVENTION

Some embodiments improve upon conventional display systems by integrating internal display components directly into a rigid, strong, conductive rear chassis. The conductive rear chassis may be configured such that internal display parts can be secured without using a secondary substructure. The conductive rear chassis may include any, or a combination, of printed circuit board (“PCB”) mounters, hinge mounters, antenna mounters, or other mounters built into the chassis itself. The conductive rear chassis may be configured to provide EMI suppression. The suppression provided by the conductive rear chassis may prevent EMI from interfering with signals sent or received by one or more antennas that may be mounted on or near the conductive rear chassis.

The conductive rear chassis may be constructed of a material that is rigid, strong, and lightweight. The conductive rear chassis may be formed from a titanium alloy. The conductive rear chassis may be formed from an aluminum alloy. The conductive rear chassis may be formed from a carbon fiber material. The conductive rear chassis may be formed from a graphite material. The conductive rear chassis may be formed from a magnesium alloy. The conductive rear chassis may be formed from a zinc alloy. The conductive rear chassis may be formed from a copper alloy. Other materials may also be used.

The conductive rear chassis may be produced by a casting method. The casting method may involve pressure injection. The casting method may involve gravity pressure. A die casting method may be used. The conductive rear chassis may be produced by a molding method. The conductive rear chassis may be produced by a stamping method. Other techniques are contemplated.

The display module may be a Liquid Crystal Display (“LCD”). The display module may be a plasma display panel (“PDP”). The display module may be a Field Emission Display (“FED”).

### BRIEF DESCRIPTION OF THE DRAWINGS

Purposes and advantages of the exemplary embodiments will be apparent to those of ordinary skill in the art from the following detailed description in conjunction with the appended drawings in which like reference characters are used to indicate like elements, and in which:

FIG. 1 is a perspective illustration of different layers of a display housing module in accordance with an exemplary embodiment;

FIG. 2 is a front view of a conductive rear chassis in accordance with an exemplary embodiment;

FIG. 3 is a schematic illustration of the frontside of a conductive rear chassis in accordance with an exemplary embodiment;

FIG. 4 is a schematic illustration of a conductive rear chassis showing various on-chassis mounters and connectors in accordance with an exemplary embodiment;

FIG. 5 is a side view of a bottom portion of a conductive rear chassis showing display inverter circuitry housed in a slot on the conductive rear chassis in accordance with an exemplary embodiment;

FIG. 6 illustrates an on-chassis display panel cushioning in accordance with an exemplary embodiment;

FIG. 7 illustrates a touch screen being placed on a display panel in accordance with an exemplary embodiment;

FIG. 8 is a up-close view of an environmental seal in accordance with an exemplary embodiment;

FIG. 9 is a front view of a display module showing the front bezel attached to the conductive rear chassis in accordance with an exemplary embodiment;

FIG. 10 illustrates the attachment of an antenna to a conductive rear chassis in accordance with an exemplary embodiment; and

FIG. 11 is a perspective view of a portable computing device with a display housing module in accordance with an exemplary embodiment.

Advantages of these and other embodiments will become apparent from the following detailed description, which taken in conjunction with the accompanying drawings, describes by way of example—and not limitation—principles of various exemplary embodiments.

### DETAILED DESCRIPTION OF EXEMPLARY EMBODIMENTS

An exemplary, non-limiting portable computing device and a display housing module for a portable computing device will be described in detail with reference to the accompanying figures. The display housing module includes a conductive rear chassis, a display module, an environmental sealer, and a front bezel. The display module may be configured to display images and may include a backlight unit, a display panel, and a touch screen. The conductive rear chassis may be constructed so as to exhibit strong, lightweight, and rigid properties. It may be configured to receive and secure a display module and to protect the display module from shock events, drop events, and vibration. The portable computing device may meet the United States Military standard for shocks, drops, and vibration (MIL STD 810F). The MIL STD 810F is a series of standards issued by the United States Army's Developmental Test Command, to specify various environmental tests to prove that equipment qualified to the standard will survive in the field. The MIL STD 810F standards are set forth in a public document entitled “Department of Defense Test Method Standard For Environmental Engineering Considerations And Laboratory Tests.” To meet the MIL STD 810F for transit drops, the portable computing device must be able to withstand drops on each face, edge and corner. It must be able to withstand 26 of these drops from a height of at least 36 inches. To meet the standard, the portable computing device must retain structural and functional integrity.

The conductive rear chassis may be configured to mount an antenna. The conductive rear chassis may prevent EMI signals from interfering with signals sent or received by an antenna. To this end, the conductive rear chassis may be configured to shield EMI that originates from noisy electronics, internal to the computer, from signals sent or received by an antenna. The conductive rear chassis may be configured to provide a conductive path to a ground connection. The conductive rear chassis may be configured to channel EMI from the noisy electronics to ground, thereby preventing unwanted EMI leakage outside the display module.

The conductive rear chassis may be further configured to receive an environmental sealer around the perimeter of the housing. The conductive rear chassis may be further configured for direct attachment to a front bezel. Attaching the front bezel to the conductive rear chassis may create pressure on the environmental sealer, thereby protecting internal display parts from environmental elements such as rain, dust, sand, chemicals, and other elements.

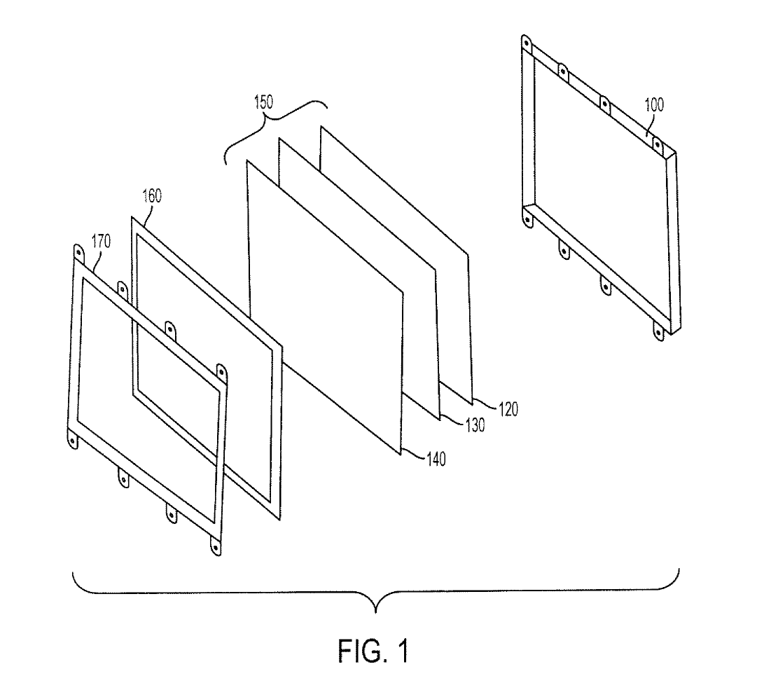

FIG. 1 is a perspective illustration of different layers of a display housing module in accordance with an exemplary embodiment. The display housing module may include a conductive rear chassis 100, a display module 150, an environmental sealer 160, and a front bezel 170. The display module 150 includes a touch screen 140, a display panel 130, and a backlight unit 120. The backlight unit 120 may include a light guide unit and a lamp unit. The light guide unit may include a light guide plate and a series of overlying sheets. The backlight unit 120 may be attached directly to the conductive rear chassis 100. To protect the display module 150, the conductive rear chassis 100 may be formed of a rigid material. Because the display module 150 is attached to and encased by a rigid chassis, the display module 150 may be less vulnerable to damage by physical impacts such as shocks, drops, or vibration. Further, the conductive rear chassis 100 may be formed of a material that dissipates heat efficiently. In this manner, the conductive rear chassis 100 may act as a thermal sink for the heat emitted by a lamp unit or other heat emitting element.

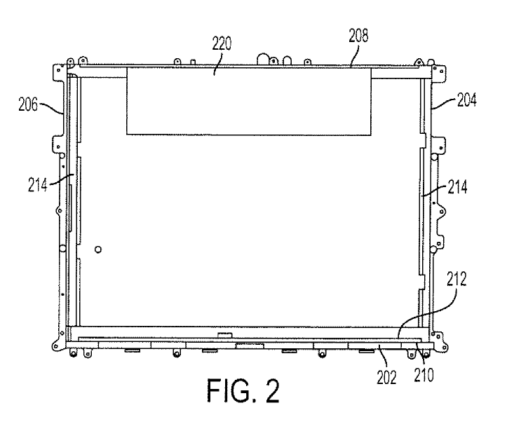

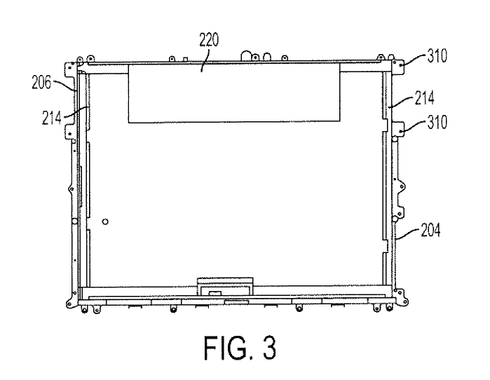

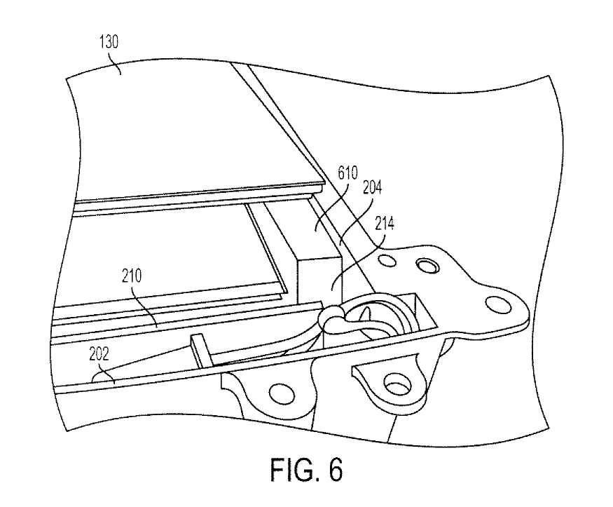

FIG. 2 is a front view of a conductive rear chassis in accordance with an exemplary embodiment. In some embodiments, the conductive rear chassis 100 is not simply a sheet; rather, it has side-walls with at least enough depth to allow for the integration of the display module 150. This depth can be seen in FIG. 2, which shows that the perimeter walls may include inward projections 214 that may be used to secure, stabilize, and cushion the display module 150. FIG. 2 also illustrates how the perimeter walls 202, 204, 206, and 208 of the conductive rear chassis 100 have inwardly directed projections 214 as built-in features of the chassis. These inwardly directed projections 214 may be any, or a combination of, slots, platforms, ridges, guides, grooves, or the like. These projections 214 may serve as a point of attachment for backlight unit 120, display panel 130 or touch screen 140. These projections may stabilize and protect the display module 150 by cushioning the fragile glass elements and securing them in a rigid chassis so that the fragile glass elements are resistant to damage from external jarring events. Projections 214 are further shown and discussed with reference to FIGS. 3 and 6.

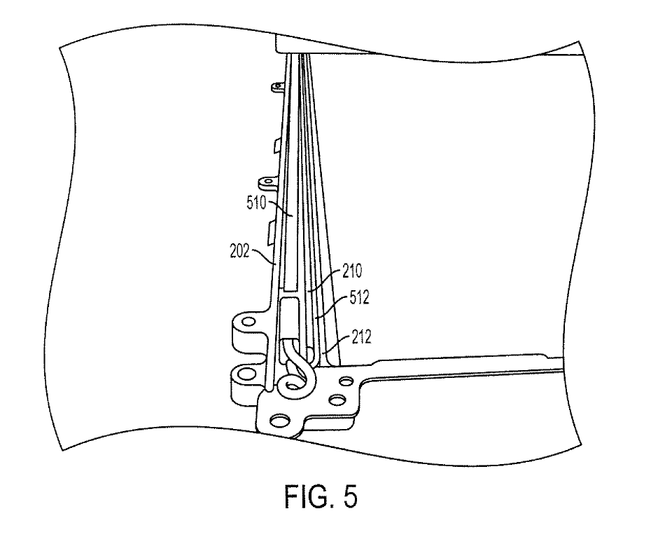

Certain additional features of the conductive rear chassis, such as the two closely spaced horizontal strips 210 and 212, may be located just above the lower perimeter wall 202 of the conductive rear chassis 100. The horizontal strips 210 and 212 are shown with a close-up view in FIG. 5, and will be further described in reference to that figure. The space between the horizontal strip 210 and the lower perimeter wall 202 may house an inverter PCB or other electronics. Such an inverter PCB converts a direct current to an alternating current to drive the backlight unit 120. The conversion from direct current to alternating current may produce unwanted EMI. The attachment of a front bezel 170 to the conductive rear chassis 100 may create a Faraday cage around the inverter PCB 510, thereby suppressing EMI. An inverter PCB is described further with reference to FIG. 5. In some embodiments, the conductive rear chassis 100 may include a cavity portion 220. The cavity portion 220 will be described further with reference to FIG. 3.

FIG. 3 is a schematic illustration of the frontside of a conductive rear chassis in accordance with an exemplary embodiment. In some embodiments, inward projections 214 are used to secure, stabilize and protect fragile glass components such as display panel 130 and touch screen 140. In other words, the fragile glass components may fit into a slot formed by the inward projections 214. The inward projections 214 may be any, or a combination of slots, platforms, ridges, guides, grooves, or the like. They may be covered with a cushioning material. The fragile glass components may sit atop a projection. The fragile glass components may be secured at their top and bottom surfaces by at least two projections on or near at least the right and left perimeter walls 204 and 206. In some embodiments, at least one antenna mounter 310 may be configured to mount at least one antenna to the conductive rear chassis 100.

In some embodiments the conductive rear chassis may include a cavity portion 220. The cavity portion 220 may allow for a slimmer display by creating additional space to house and shield electronic circuitry. An example of such electronic circuitry is a display driver that helps create the images that appear on the display panel. The display driver may produce EMI.

In some embodiments, the cavity portion may be formed as a depression area in the conductive rear chassis 100. In such embodiments, a slimmer display may be achieved while keeping the continuity of the conductive rear chassis 100 intact. In some embodiments the cavity portion 220 may be formed by cutting out a portion of the conductive rear chassis 100 and then adhering a conductive member back over top of the removed portion. The conductive member may be thin sheet-like metal or a metallized plastic material. It should be appreciated that FIG. 3 is merely exemplary, and that the cavity portion 220 may vary in size, shape, and location on the conductive rear chassis 100.

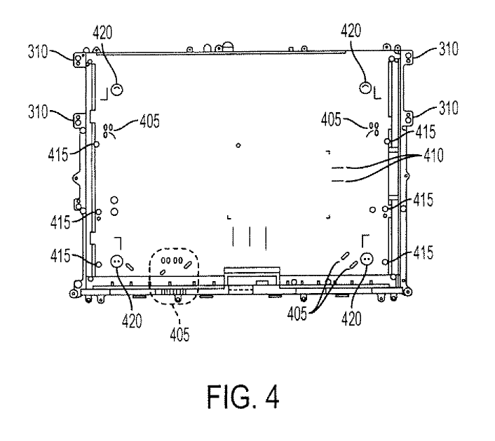

FIG. 4 is a schematic illustration of a conductive rear chassis showing various on-chassis mounters and connectors in accordance with an exemplary embodiment. This figure illustrates many different varieties of mounters that may be built into the conductive rear chassis 100 to facilitate attachment with the conductive rear chassis 100. Some mounters may be disposed on the inside surface of the chassis. Some mounters may be disposed on the outside surface of the chassis. In some embodiments at least one PCB mounter 410 may be configured to mount at least one PCB to the conductive rear chassis 100. In some embodiments, at least one antenna mounter 310 may be configured to mount at least one antenna to the conductive rear chassis 100. In some embodiments, at least one antenna cable routing guide 405 may be configured to allow attachment of an antenna cable, which may provide a communication link between an antenna mounted on an antenna mounter 310 and on-board electronic circuitry. The at least one PCB may contain circuitry, such as a display driver, that produces EMI. The EMI produced at the at least one PCB could potentially interfere with signals being sent to and from the at least one antenna. The conductive rear chassis 100 may provide EMI shielding to prevent EMI originating from the electronic circuitry from interfering with antenna signals.

EMI may be created when electrical current is driven through a wire, such as a trace on a PCB. The trace may then act as an EMI transmitter, and this may become problematic if the transmitted EMI begins to interfere with signals being sent to or from a nearby antenna. The conductive rear chassis 100 may act as a conductive partition between the electronic circuitry and the antenna, and may consequently act as an EMI shield. When EMI comes in contact with the conductive rear chassis 100, a current may flow on the conductive rear chassis 100 to ground. EMI is thus attenuated by a force called the skin effect. It should be appreciated that an ungrounded EMI shield that completely surrounds a noisy device can provide effective EMI shielding. Such an enclosure is known as a Faraday cage and results in two-way EMI shielding (i.e., EMI can neither enter nor exit the shield). The Faraday cage does not have to be fully enclosed to the extent that there are no gaps, cracks, or holes at all. There can be gaps, cracks, or holes in the enclosure, but they can be no bigger than the EMI's wavelength. If there are gaps, cracks, or holes larger than the EMI's wavelength, the enclosure does not provide the shielding benefits of a true Faraday cage. In some instances, it may be difficult or impractical to surround a device with an enclosure that qualifies as a true Faraday cage. However, EMI can still be effectively shielded without the existence of a true Faraday cage. In this situation, the EMI can be effectively shielded if the shielder lies between the EMI source and the antenna to be shielded, and is grounded or has its voltage potential defined with respect to the source of the EMI. The conductive rear chassis 100 can effectively shield antenna signals from EMI that originates from PCB circuitry, such as a display driver, because (1) it provides a conductive spatial partition between the PCB and the antenna, and (2) it shares a ground connection with the EMI source on the PCB. The at least one PCB mounter 410 may be configured to mount the at least one PCB such that the ground connection of the PCB is in contact—and thus electrically linked—with the conductive rear chassis 100. The connection between the conductive rear chassis 100 and the PCB is not susceptible to physical separation because the conductive rear chassis 100 is constructed of a rigid material. Specifically, the rigidity of the conductive rear chassis 100 may prevent a PCB ground connection from losing connectivity with the conductive rear chassis 100 as a result of a jarring event such as a shock, drop, or vibration. The grounding of the conductive rear chassis 100 may protect from shock hazards by providing a fault-current return path. Further, grounding the conductive rear chassis 100 may prevent the buildup of voltage on the chassis itself.

In some embodiments the conductive rear chassis 100 may include a cavity portion 220. The cavity portion 220 may be formed as a depression area in the conductive rear chassis 100. The cavity portion 220 may also be formed by cutting out a portion of the conductive rear chassis 100 and then adhering a conductive member back over top of the removed portion. The conductive member may be thin insulated sheet-like metal or an insulated metallized plastic material. A PCB may be mounted or adhered in the cavity portion 220. When the cavity portion 220 is a cut-out area, the PCB may be mounted or adhered to the insulated sheet-like metal or the insulated metallized plastic material which may have been adhered back over the top of a removed portion. The PCB may be mounted or adhered on the sides or bottom of the cut-out area. When the cavity portion 220 is a depression, the PCB may be mounted or adhered on the sides or bottom of the depression area.

In some embodiments, hinge mounters 415 may be configured to mount a display housing module to the base of a portable computing device. Hinge mounters 415 may be configured to attach to the base unit of a portable computing device to allow the display module to rotate about the hinge. Hinge mounter 415 may allow for forward and backward rotation and may also allow for the display module to be rotated or twisted to the left or the right with respect to the base unit of a portable computing device. In some embodiments, external cover mounters 420 may be configured to mount a decorative covering. Additionally, external cover mounters 420 may be configured to mount external attachments that may facilitate carrying the portable computing device (e.g. a handle), or docking or attaching the portable computing device.

FIG. 5 is a side view of a bottom portion of a conductive rear chassis showing display inverter circuitry housed in a slot on the conductive rear chassis in accordance with an exemplary embodiment. An inverter PCB 510 may be disposed below a lower horizontal strip 210 and above the bottom perimeter wall 202 on the inside surface of the conductive rear chassis 100. The inverter PCB 510 may be mounted to the inside surface of the chassis. The inverter PCB 510 may be enclosed by the lower horizontal strip 210 and the perimeter wall 202 without being mounted. To that end, the horizontal strip 210 may be spaced from the perimeter wall 210 such that the inverter PCB 510 may be enclosed without being mounted. The inverter PCB 510 may be mounted to the perimeter wall 202 and the lower horizontal strip 210. In some embodiments, the spacing between horizontal strip 210 and horizontal strip 212 may provide sufficient room for the inverter cable 512 carrying alternating current output from the inverter PCB 510.

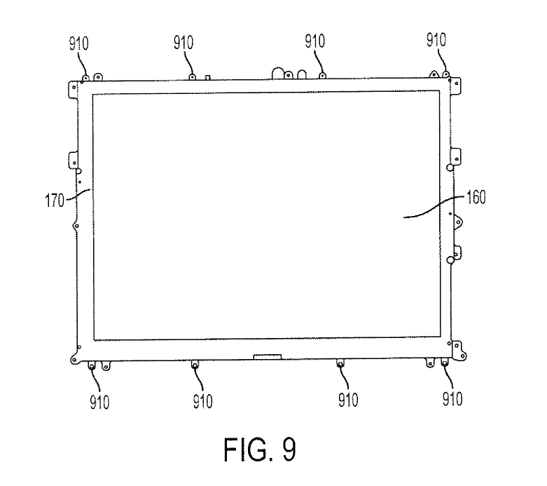

The lower horizontal and upper horizontal strips 210 and 212, and the wall of the bottom perimeter 202 are both conductive as they are a part of the conductive rear chassis 100. Configuring the conductive rear chassis 100 such that the EMI emitting PCB 510 is sandwiched between two conductive strips allows for effective EMI noise suppression because the emitted electromagnetic radiation follows the conductive path of least resistance to ground, and noise emission is thereby reduced. The EMI suppression effect is further enhanced by the attachment of a front bezel 170, which is illustrated at FIG. 9 and discussed in relation to that figure. This attachment creates a full conductive enclosure around the inverter PCB 510 and the inverter cable 512. In this way, the attachment of the front bezel 170 may result in a Faraday cage being formed around the inverter PCB 510 and inverter cable 512. Any unwanted EMI is contained by the Faraday cage.

FIG. 6 illustrates an on-chassis display panel cushioning in accordance with an exemplary embodiment. A projection 214 is shown in conjunction with right perimeter wall 204. This projection may serve as a resting place for display panel 130. The display panel cushion 610 may be attached to this projection and other projections near the perimeter of the conductive rear chassis 100. This display panel cushion 610 may be constructed of a rubberlike material that cushions or pads the fragile display panel 130 in the event of jarring to the display module such as a shock, drop or vibration.

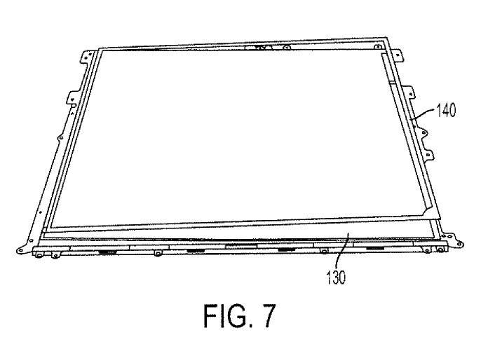

FIG. 7 illustrates a touch screen being placed on a display panel in accordance with an exemplary embodiment. In some embodiments, a touch screen 140 goes over top of a display panel 130. The touch screen 140 may be anti-reflective to improve viewing while outdoors. The touch screen 140 may be coated for extra glare reduction. The touch screen 140 may be capacitive, resistive, or utilize a different technology. The touch screen 140 may rest along the inward projections that are built-in to the conductive rear chassis and covered with a rubberlike cushion. The touch screen may be further cushioned on the top and on the sides by an environmental sealer 160.

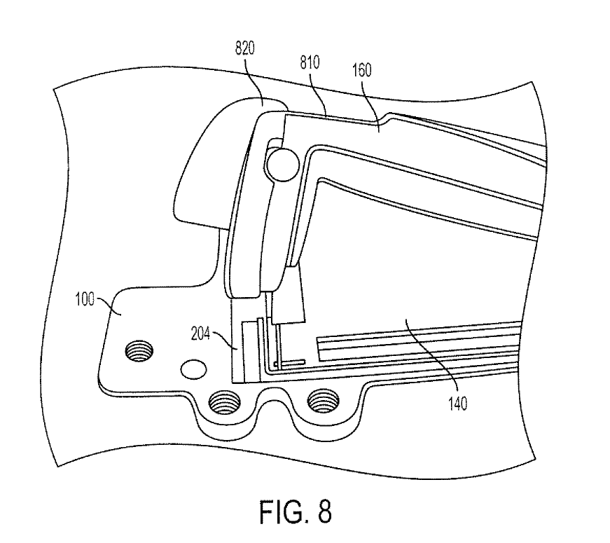

FIG. 8 is an up-close view of an environmental sealer in accordance with an exemplary embodiment. The illustration shows an environmental sealer 160 as it covers a touch screen 140. The environmental sealer 160 may be configured to prevent environmental elements such as rain, dust, sand, chemicals, or other elements that may harm the functionality of display internals from coming in contact with the display internals. The environmental sealer 160 may be made of a rubberlike material. The environmental sealer may include a rib 810 to help ensure that the touch screen 140 is tightly sealed. The environmental sealer 160 may also include a rubberlike cushion 820 to protect the fragile touch screen 140 from making contact with a perimeter wall 204 of the conductive rear chassis 100. The environmental sealer 160 may be disposed about the entire perimeter of the touch screen 140. The combination of the rib 810 and the rubberlike cushion 820 create a tight enough seal around the touch screen 140 that the rest of the display module 150 is totally protected from water submersion, rain, sand, dust, or exposure to toxic chemicals.

FIG. 9 is a front view of a display module showing the front bezel attached to the conductive rear chassis in accordance with an exemplary embodiment. Attaching the front bezel 170 to the conductive rear chassis 100 creates pressure on the environmental sealer 160, which provides additional sealing protection. The front bezel 170 may be attached to the conductive rear chassis 100 with bezel attachers 910. In the illustration, there are eight bezel attachers 910; however, it should appreciated that this illustration is merely exemplary. The bezel attachers 910 may be configured such that the attachment between bezel 170 to the conductive rear chassis 100 creates an electrical connection between those two conductive surfaces. In this way, the attachment of the front bezel 170 may result in a Faraday cage being formed around the inverter PCB 510, and unwanted EMI is thereby contained.

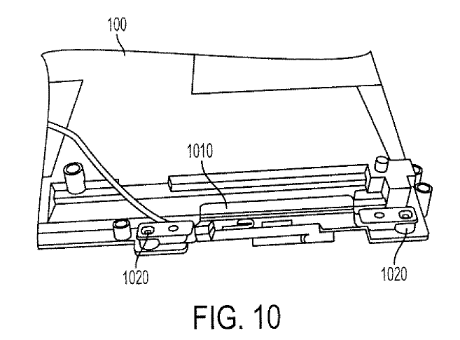

FIG. 10 illustrates the attachment of an antenna to a conductive rear chassis in accordance with an exemplary embodiment. In some embodiments, an antenna 1010 may be configured to send and receive signals using different wireless standards. The antenna 1010 may be configured to communicate over a communications protocol associated with a wide area network (WAN). The antenna 1010 may be configured to communicate over a communications protocol associated with a local area network (LAN). The antenna 1010 may be configured to communicate over a communications protocol associated with a personal area network (PAN). The antenna 1010 may be configured to communicate using the worldwide interoperability for microwave access (WiMAX) standard. The antenna 1010 may be configured to send and receive signals using multiple communications protocols, simultaneously or sequentially. The antenna may be used by a GPS device

In some embodiments, the antenna 1010 may be attached to the conductive rear chassis through antenna mounter 1020. The antenna mounter 1020 may be disposed on the inside or outside surface of the conductive rear chassis 100. An antenna mounter 1020 may be located or positioned to ensure that EMI produced by electronic circuitry used to drive the display of images is shielded from the signals sent and received by the antenna. The conductive rear chassis 100 may provide such shielding.

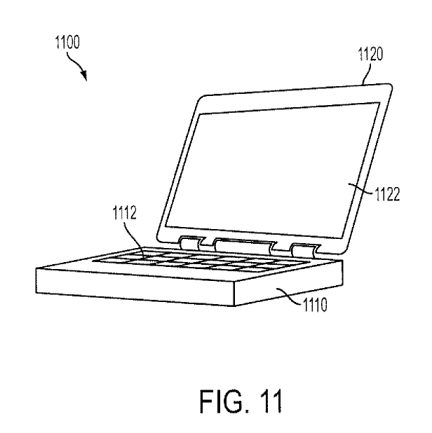

FIG. 11 is a perspective view of a portable computing device with a display housing module in accordance with an exemplary embodiment. FIG. 11 illustrates a computing device 1100. The illustration depicts what is commonly referred to as a “laptop” or “notebook” computer. However, it should be appreciated that the various embodiments described throughout this specification are not limited to a laptop or notebook computer and are usable on any computing device or any device that incorporates a display, such as, by way of non-limiting example, a television. In some embodiments, a display housing module 1120 with a touch screen 1122 may be integrated with a base unit 1110 of a computing device 1100. The base processing module 1110 may include a top surface and a keyboard module 1112 may be coupled onto the top surface of the base processing module. The display housing module 1120 may be connectively coupled with a display housing module 1120. The display housing module 1120 and the base processing module 1110 may be coupled such that the display housing module 1120 is rotatable about the connection to the base processing module 1110.

The preceding specification makes repeated reference to Printed Circuit Boards (“PCB”). It should be appreciated that the term PCB is a generic term that includes both rigid and other types of circuit boards, such as, by way of non-limiting example, Flexible Printed Circuits (“FPC”).

In the preceding specification, various preferred embodiments have been described with reference to the accompanying drawings. It will, however, be evident that various modifications and changes may be made thereto, and additional embodiments may be implemented, without departing from the broader scope of the invention as set forth in the claims that follow. The specification and drawings are accordingly to be regarded in an illustrative rather than restrictive sense.

1. A display housing module for a portable computer, comprising:
a display module, having an outer perimeter, configured to display images based at least in part on signals originating from at least one electronic printed circuit board;
a conductive rear chassis configured to receive the display module; and
an environmental sealer extending about the perimeter of the display module;
wherein the conductive rear chassis is attached to a front bezel, whereby the front bezel creates pressure on the environmental sealer;
wherein the conductive rear chassis is shaped as a rectangular container and includes sidewalls along the perimeter of the chassis;
wherein the conductive rear chassis comprises a ground connection;
wherein the conductive rear chassis comprises at least one printed circuit board mounter configured to electrically link the at least one electronic printed circuit board with the conductive rear chassis, whereby electromagnetic interference originating from the at least one electronic printed circuit board is channeled to ground and thereby suppressed;
wherein the conductive rear chassis is formed of a material selected from the group consisting of: titanium, aluminum, and zinc.

2. The display housing module according to claim 1 wherein the conductive rear chassis comprises at least one antenna mounter.

3. The display housing module according to claim 2, wherein at least one antenna is mounted to the conductive rear chassis.

4. The display housing module according to claim 3, wherein the at least one mounted antenna is configured to send and receive signals using protocols selected from the group consisting of: GPS, WAN, LAN, PAN, and WiMAX.

5. The display housing module according to claim 4, wherein the conductive rear chassis prevents interference with antenna signals by shielding the antenna from electromagnetic interference originating from the at least one electronic printed circuit board.

6. The display housing module according to claim 2, wherein the conductive rear chassis comprises at least one hinge mounter.

7. The display housing module according to claim 3, wherein the conductive rear chassis comprises at least one external decorative cover mounter.

8. The display housing module according to claim 1, wherein the display module comprises a backlight unit, a display panel, and a touch screen.

9. The conductive rear chassis according to claim 1, further comprises a display panel holder, wherein the display panel holder comprises inward projections disposed about at least two perimeter walls of the chassis, whereby the inward projections are configured to receive and secure a display panel.

10. The display housing module according to claim 9, wherein the display panel holder is covered by a rubberlike display panel cushion along the perimeter walls.

11. A display housing module for a portable computer, compri sing:
a display module, having an outer perimeter, configured to display images based at least in part on signals originating from at least one electronic printed circuit board;
a conductive rear chassis configured to receive the display module; and
an environmental sealer extending about the perimeter of the display module;
wherein the conductive rear chassis is attached to a front bezel, whereby the front bezel creates pressure on the environmental sealer;
wherein the conductive rear chassis is shaped as a rectangular container and includes sidewalls along the perimeter of the chassis;
wherein the conductive rear chassis comprises a ground connection;
wherein the conductive rear chassis comprises at least one printed circuit board mounter configured to electrically link the at least one electronic printed circuit board with the conductive rear chassis, whereby electromagnetic interference originating from the at least one electronic printed circuit board is channeled to ground and thereby suppressed;
wherein the conductive rear chassis is formed of a carbon material.

12. The display housing module according to claim 11 wherein the conductive rear chassis comprises at least one antenna mounter.

13. The display housing module according to claim 12, wherein at least one antenna is mounted to the conductive rear chassis.

14. The display housing module according to claim 13, wherein the at least one mounted antenna is configured to send and receive signals using protocols selected from the group consisting of: GPS, WAN, LAN, PAN, and WiMAX.

15. The display housing module according to claim 4, wherein the conductive rear chassis prevents interference with antenna signals by shielding the antenna from electromagnetic interference originating from the at least one electronic printed circuit board.

16. The display housing module according to claim 12, wherein the conductive rear chassis comprises at least one hinge mounter.

17. The display housing module according to claim 13, wherein the conductive rear chassis comprises at least one external decorative cover mounter.

18. The display housing module according to claim 11, wherein the display module comprises a backlight unit, a display panel, and a touch screen.

19. The rear conductive housing according to claim 11, further comprises a display panel holder, wherein the display panel holder comprises inward projections disposed about at least two perimeter walls of the chassis, whereby the inward projections are configured to receive and secure a display panel.

20. The display housing module according to claim 19, wherein the display panel holder is covered by a rubber like display panel cushion along the perimeter walls.

21. A portable computing device comprising a base processing module, a keyboard module, and a display module comprising:
a base processing module comprising a top surface;
a keyboard module coupled to the top surface of the base processing module; and
a display housing module connectively coupled to the base processing module comprising:
a display module configured to display images based at least in part on signals originating from at least one electronic printed circuit board;
a conductive rear chassis configured to receive the display module; and
an environmental sealer extending about the perimeter of the display module;
wherein the conductive rear chassis is attached to a front bezel, whereby the front bezel creates pressure on the environmental sealer;
wherein the conductive rear chassis is shaped as a rectangular container and includes sidewalls along the perimeter of the chassis;
wherein the conductive rear chassis comprises a ground connection;
wherein the conductive rear chassis comprises at least one printed circuit board mounter configured to electrically link the at least one electronic printed circuit board with the conductive rear chassis, whereby electromagnetic interference originating from the at least one electronic printed circuit board is channeled to ground and thereby suppressed;
wherein the conductive rear chassis is formed of a material selected from the group consisting of titanium, aluminum, and zinc.

22. The portable computing device of claim 21, wherein the portable computing device meets the United States Military standard, MIL STD 810F, for drops, shocks, and vibration.

23. A portable computing device comprising a base processing module, a keyboard module, and a display module comprising:
a base processing module comprising a top surface;
a keyboard module coupled to the top surface of the base processing module;
a display housing module connectively coupled to the base processing module comprising:
a display module configured to display images based at least in part on signals originating from at least one electronic printed circuit board;
a conductive rear chassis configured to receive the display module; and
an environmental sealer extending about the perimeter of the display module;
wherein the conductive rear chassis is attached to a front bezel, whereby the front bezel creates pressure on the environmental sealer;
wherein the conductive rear chassis is shaped as a rectangular container and includes sidewalls along the perimeter of the chassis;
wherein the conductive rear chassis comprises a ground connection,
wherein the conductive rear chassis comprises at least one printed circuit board mounter configured to electrically link the at least one electronic printed circuit board with the conductive rear chassis, whereby electromagnetic interference originating from the at least one electronic printed circuit board is channeled to ground and thereby suppressed;
wherein the conductive rear chassis is formed of a carbon material.

24. The portable computing device of claim 23, wherein the portable computing device meets the United States Military standard, MIL STD 810F, for drops, shocks, and vibration.

25. A display housing module for a portable computer, comprising:
a display module configured to display images based at least in part on signals originating from at least one electronic printed circuit board;
means for housing the display module;
means for protecting the display module from environmental elements such as water, dust, sand, and chemicals;
means for attaching a bezel to the conductive rear chassis;
an antenna mounted to the conductive rear chassis, whereby the antenna is configured to send and receive signals;
means for preventing at least some electromagnetic interference originating from the at least one electronic printed circuit board from interfering with signals sent to and from the antenna; and
means for dissipating heat originating from the display module;
wherein the means for housing the display module is formed from a non-magnesium material.
